(19) United States
(12) Patent Application Publication
(10) Pub. No.: US 2009/0039381 A1
(43) Pub. Date: Feb. 12, 2009

(54) LIGHT EMITTING DIODE PACKAGE AND METHOD OF MANUFACTURING THE SAME

(75) Inventors: Dong-Soo KIM, Ansan-si (KR); Haw-Kyung Choi, Dalseong-gu (KR)

Correspondence Address: THE FARRELL LAW FIRM, P.C., 333 EARLE OVINGTON BOULEVARD, SUITE 701, UNIONDALE, NY, 11553, US

(73) Assignee: Alti-electronics Co., Ltd., Yongin-si (KR)

(21) Appl. No.: 12/187,838

(22) Filed: Aug. 7, 2008

(30) Foreign Application Priority Data
Aug. 10, 2007 (KR) 2007-0080701

(51) Int. Cl. H01L 33/00; H01L 21/50

(52) U.S. Cl. 257/99; 438/26; 257/E33.056; 257/E21.499

(57) ABSTRACT

An LED package is disclosed. The LED package includes a substrate having a plurality of sub patterns adhered by insulation adhesive, an LED chip mounted on the substrate and electrically connected to the substrate and a molding cap covering the LED chip. According to the LED package, as well as simplifying structure, an obstacle is removed at a light course of light emitted from the LED chip, so that light efficiency of the LED chip is improved.

### CROSS-REFERENCE TO RELATED APPLICATIONS

This application claims priority under 35 U.S.C. § 119 to Korean Patent Application No. 10-2007-0080701, filed on Aug. 10, 2007 in the Korean Intellectual Property Office (KIPO), the contents of which are herein incorporated by reference in their entirety.

### BACKGROUND OF THE INVENTION

1. Field of the Invention

The present invention relates to a light emitting diode (“LED”) package and a method of manufacturing the LED package. More particularly, the present invention relates to an LED package for display lamp used in various electrical devices and a method of manufacturing the LED package.

2. Description of the Related Art

As well as development for information telecommunication, development for semiconductor technique is expected to lead to revolution of new light.

The light emitting diode known as an LED is for displaying characters or numbers in electronic devices, and is an intermetallic compound adhesive diode emitting light when electrical current flows at P-N junction of the semiconductor.

FIG. 1 is a cross-sectional view illustrating a conventional light emitting diode (“LED”).

Referring to FIG. 1, an LED package 10 includes a lead frame 11, an LED chip 12 mounted on the lead frame 11, a heat sink 13 dissipating heat from the LED chip 12, a wire electrically connecting the lead frame 11 and the LED chip 12, a housing 15 surrounding the lead frame 11 to open an upper part of the LED chip 12 and a sealing part 16 covering an upper part of the opened LED chip 12.

The housing 15 is formed by the injection molding method of polymer resin. Recently, the housing 15 is formed at an angle to make an angle between an inside surface of the opening on the housing 15 and the lead frame 11, thereby improving light characteristics such as brightness of light from the LED chip 12.

When the LED chip 12 emits light toward the outside of the LED 10, the light is absorbed by the housing 15 of the LED 10 at the light course or the light course is changed by the housing, so that light efficiency is lowered.

### SUMMARY OF THE INVENTION

The present invention provides a light emitting diode (“LED”) package improving light efficiency of light emitted from an LED chip and a method of manufacturing the LED package.

In an exemplary embodiment, a LED package includes a substrate having a plurality of sub patterns adhered by insulation adhesive; an LED chip mounted on the substrate and electrically connected to the substrate; and a molding cap covering the LED chip.

In an exemplary embodiment, as a method of manufacturing an LED package, a plurality of sub patterns is formed to form a substrate pattern at a conductive frame, and the sub patterns are combined by insulation adhesive to form a substrate, and an LED chip is mounted on the substrate, and a molding cap is formed on the substrate to cover the LED chip.

According to the present invention, an obstacle is removed at a light source of light from an LED chip by combining sub patterns working as electrodes to be insulated to provide a substrate mounting the LED chip, sealing the LED chip with a sealing cap. Thus, light efficiency lowering according to light absorption and light course change by a conventional housing is prevented.

### BRIEF DESCRIPTION OF THE DRAWINGS

The above and other advantages of the present invention will become readily apparent by reference to the following detailed description when considered in conjunction with the accompanying drawings wherein:

FIG. 1 is a cross-sectional view illustrating a conventional light emitting diode (“LED”);

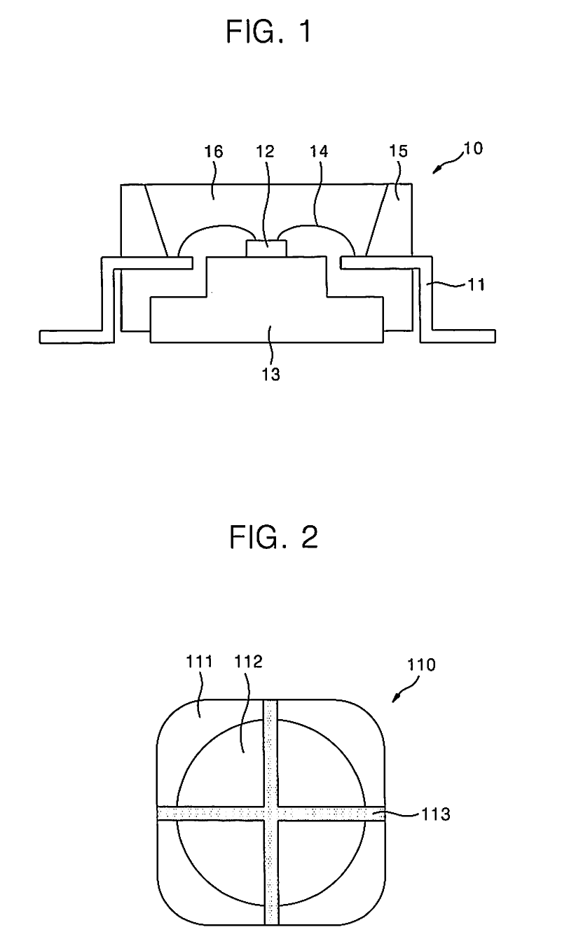

FIG. 2 is a plan view illustrating a substrate in accordance with an embodiment of the present invention;

FIG. 3 is a perspective view illustrating an LED package in accordance with an embodiment of the present invention;

FIG. 4 is a flow chart showing a method of manufacturing an LED package in accordance with an embodiment of the present invention;

FIGS. 5A to 5D are plan views illustrating the method of manufacturing the LED package in accordance with the embodiment of the present invention; and

FIGS. 5E to 5F are perspective views illustrating the method of manufacturing the LED package in accordance with the embodiment of the present invention.

### DESCRIPTION FOR NUMERAL REFERENCES IN DRAWINGS

| | |
|---|---|
| 100, 200: LED package | 110, 120: substrate |
| 111, 211: sub pattern | 112, 214: cap receiving part |
| 113, 215: insulation adhesive | 130, 220: LED chip |
| 140, 230: wire | 150, 240: molding cap |
| 210′: substrate pattern | 300: mask |
| 310: opening | |

### DESCRIPTION OF THE EMBODIMENTS

Hereinafter, the present invention will be described in detail with reference to the accompanying drawings.

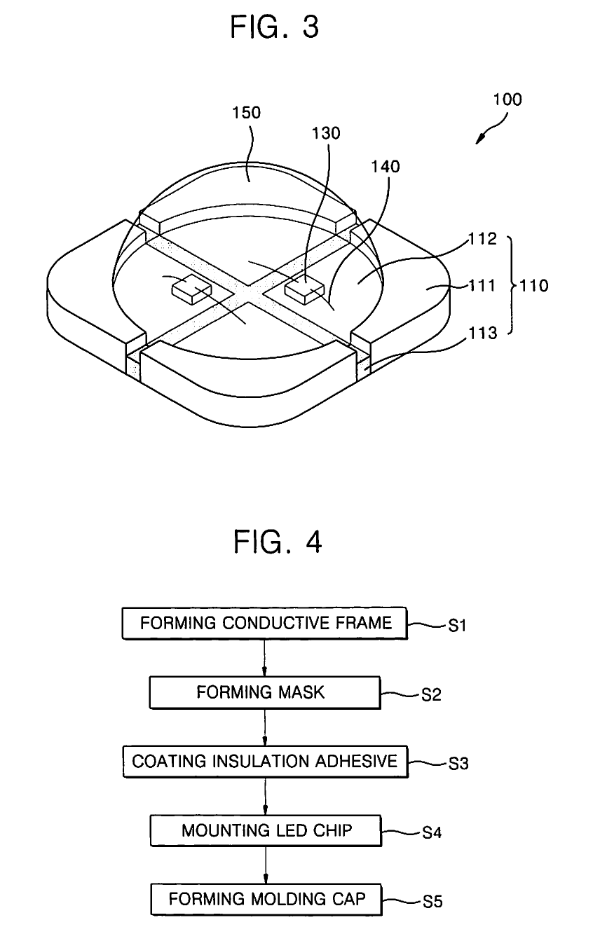

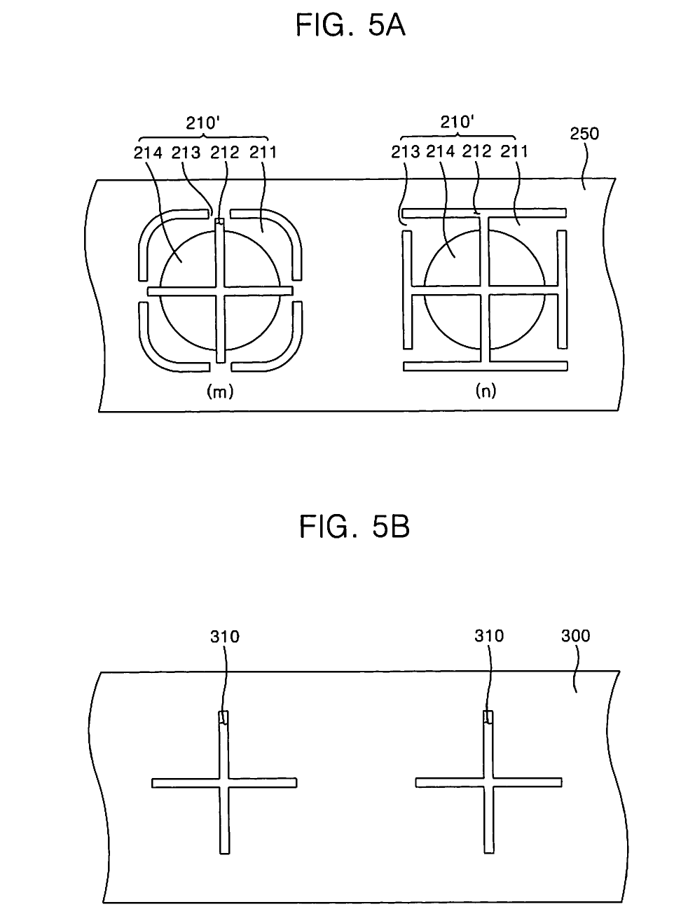

FIG. 2 is a plan view illustrating a substrate in accordance with an embodiment of the present invention. FIG. 3 is a perspective view illustrating an LED package in accordance with an embodiment of the present invention.

Referring to FIGS. 2 and 3, a light emitting diode (“LED”) package 100 includes a substrate 110, an LED chip 130 mounted on the substrate 110 and a molding cap 150 covering the LED chip 130.

The substrate 110 includes a plurality of sub patterns 111, and a plurality of the sub patterns 111 may be adhered to each other by an insulation adhesive 120.

At a center part of the substrate 110 having the adhered sub patterns 111, a cap receiving part 112, at which thickness is thinner than peripheral areas to form a stepped portion, may be formed.

Each of the sub patterns 111 are functioned as electrodes, and are insulated to each other in order to prevent from an electrical short.

The number of the sub patterns 111 may be decided by an electrical connecting type and connecting method of the LED chip 130 mounted on the substrate 110.

For example, the number of the sub patterns 111 may be different when a plurality of the LED chips 130 is connected in serial from when a plurality of the LED chip 130 is connected in parallel.

Moreover, the number of the sub patterns 111 may be decided on whether the sub pattern 111 and the LED chip 130 are electrically and indirectly connected by a conductive wire 140 or not. The number of sub patterns 111 may be decided on whether the sub pattern 111 and the LED chip 130 are electrically and directly connected or not. Since the LED chip 130 uses the sub pattern 111 as a positive electrode and a negative electrode.

The molding cap 150 protects the LED chip 130 from external shock and works as a lens for dispersing light emitted from the LED chip 130.

The molding cap 150 may have an oval shape for distribution of an optic angle, and may have a corn shape or a shape having a concave upper surface for improving uniformity of light or color mixture.

The molding cap 150 is received on the cap receiving part 112, and is fixed by the stepped portion of the cap receiving part 112 to prevent position movement by external shock.

By the LED package 100 as described the above, an obstacle such as a housing (not shown) is not disposed at a light source emitted from the LED chip 130 toward the outside, so that light efficiency of the LED chip 130 is improved.

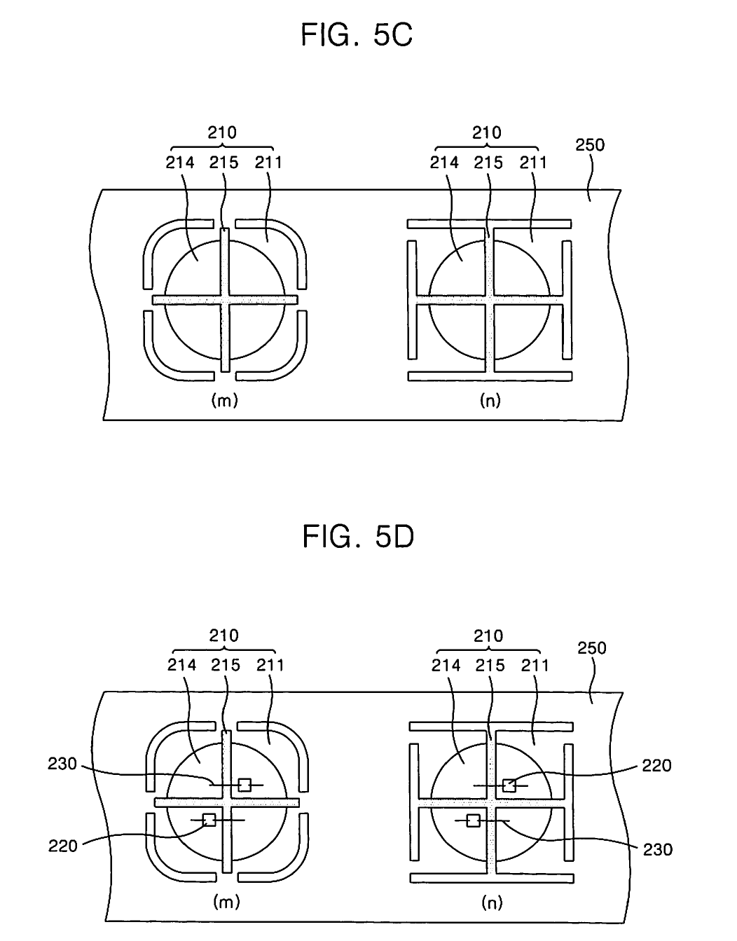

FIG. 4 is a flow chart showing a method of manufacturing an LED package in accordance with an embodiment of the present invention.

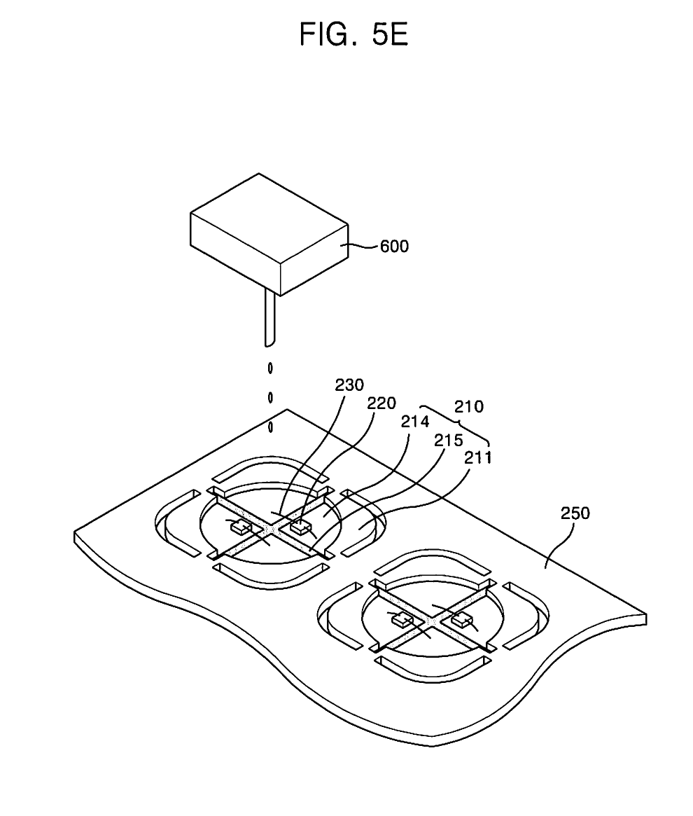

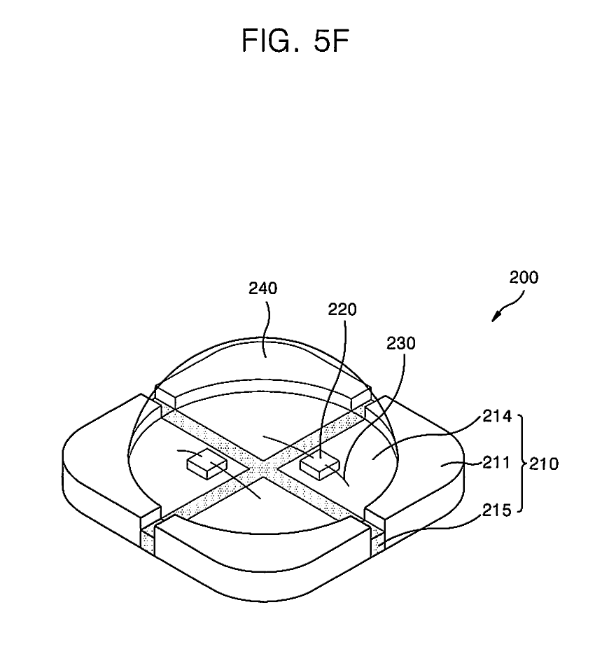

FIGS. 5A to 5D are plan views illustrating the method of manufacturing the LED package in accordance with the embodiment of the present invention.

FIGS. 5E to SF are perspective views illustrating the method of manufacturing the LED package in accordance with the embodiment of the present invention.

Referring to S1 in FIG. 4 and FIG. 5A, a conductive frame 250 is patterned to form a substrate pattern 210′ as a matrix shape.

The substrate pattern 210′ includes a connecting part 213 and a separating part 212. The connecting part 213 connects sub patterns 211 separated from each other to the conductive frame 250, and the separating part 212 separates each of the sub patterns 211.

The substrate pattern 210′ may be patterned by forming an outline of the sub patterns 211, the connecting part 213 and the separating part 212, and the cap receiving part 212 may be formed by forming the stepped portion having thinner at the center part than at the peripheral parts.

The substrate pattern 210′ may be formed by a stamping process.

The substrate pattern 210′ may be formed as various shapes according to a design, and the ‘m’ and ‘n’ shapes illustrated in the drawings are embodiments of the substrate pattern 210′. Thus, the substrate pattern 210′ is not limited to the ‘m’ and ‘n’ shapes.

Referring to S2 of FIG. 4 and FIG. 5B, as well as forming the substrate pattern 210′, a mask 300, at which an opening 310 having substantially the same shape with the separating part 212, is provided.

The opening part 310 is formed on the mask overlapping with the separating part 212.

The steps of S1 and S2 may be switched in process order, or may proceed simultaneously.

Referring to S3 of FIG. 4 and FIG. 5C, in order to form the substrate 210 adhering the sub patterns 211, an insulation adhesive 215 is coated on the separating part 212 of the substrate pattern 210′ by a method such as a printing after overlapping the conductive frame 250 with the mask 300.

The mask 300 is overlapped on the conductive frame 250 to correspond the opening 310 of the mask 300 to the separating part 212 of the substrate pattern 210′, and the insulation adhesive 215 is coated on the mask 300 to inject the insulation adhesive to the separating part 212 through the opening part 310, so that the sub patterns 211 are adhered to each other.

The substrate pattern 210′ formed on the conductive frame 250 becomes the substrate 210 by the process mentioned the above.

Referring to S4 in FIG. 4 and FIG. 5D, the proper number of LED chip 220 is mounted on the substrate 210, and the substrate 210 and the LED chip 220 are connected electronically.

The electrical connection between the substrate 210 and the LED chip 220 may be connected to the sub pattern 211 having the LED chip 220 and the adjacent sub pattern 221 by two conductive wires 230, respectively.

The electrical connection is not limited as illustrated in the drawings. For example, the sub pattern 211 adjacent to the LED chip 220 mounted on the sub pattern 211 may be connected by a wire, and the sub pattern 211 may be connected directly. Moreover, when only the mounted sub pattern 211 may be connected, the structure of the sub pattern 211 is changed to form a positive electrode and a negative electrode in the sub pattern 211.

Referring to S5 in FIG. 4 and FIGS. 5E and 5F, the molding cap 240 is formed on the molding cap 240 to protect the LED chip from the outside and to distribute an optical angle, and the molding cap 240 is formed by supplying polymer resin to the cap receiving part 214 on the substrate 210 from a catapult 600.

Finally, a plurality of substrates 210 is cut to form the LED package 200 as illustrated.

According to the present invention, as well as simplifying a structure, an obstacle at a light source from the LED chip to the outside of a chip is not disposed, so that light efficiency is improved.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A light emitting diode (“LED”) package comprising:
a substrate having a plurality of sub patterns adhered by an insulation adhesive;
an LED chip mounted on the substrate and electrically connected to the substrate; and
a molding cap covering the LED chip.

2. The LED package of claim 1, wherein a shape of the molding cap is one of an oval shape, a corn shape and a shape having a concave upper surface.

3. The LED package of claim 1, wherein each of the sub patterns includes an electrode, which is mutually independent from an adjacent electrode.

4. The LED package of claim 1, wherein the substrate includes a cap receiving part, at which thickness is thinner than peripheral areas to form a stepped portion, and the molding cap is received at the cap receiving part and the position of the molding cap is fixed by the stepped portion of the cap receiving part.

5. A method of manufacturing an LED package comprising:
forming a plurality of sub patterns to form a substrate pattern at a conductive frame;
combining the sub patterns by insulation adhesive to form a substrate;
mounting an LED chip on the substrate; and
forming a molding cap on the substrate to cover the LED chip.

6. The method of manufacturing the LED package of claim 5, wherein the substrate pattern includes a separating part, which separates the sub pattern, a connecting part connecting the sub pattern to the conductive frame and a separating part separating the sub pattern.

7. The method of manufacturing the LED package of claim 6, wherein the insulation adhesive is provided to the separating part by using a mask having an opening corresponding to the separating part.

8. The method of manufacturing the LED package of claim 5, wherein the substrate pattern is formed by forming outlines of the sub patterns and by forming a cap receiving part to form a stepped portion, at which thickness is thinner than peripheral areas to form a stepped portion.
